(19) United States
(12) Patent Application Publication
(10) Pub. No.: US 2013/0099075 A1
(43) Pub. Date: Apr. 25, 2013

(54) SUPPORT DEVICE

(71) Applicants: JIN-XIN WANG, Shenzhen City (CN); BEN-XIANG ZHAO, Shenzhen City (CN); WU-ZHU HU, Shenzhen City (CN); WU-QI LI, Shenzhen City (CN); TANG LI, Shenzhen City (CN)

(72) Inventors: JIN-XIN WANG, Shenzhen City (CN); BEN-XIANG ZHAO, Shenzhen City (CN); WU-ZHU HU, Shenzhen City (CN); WU-QI LI, Shenzhen City (CN); TANG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/525,552

(22) Filed: Jun. 18, 2012

(30) Foreign Application Priority Data
Oct. 21, 2011 (CN) 201110322693.2

(51) Int. Cl. H05K 7/00; F16B 47/00; F16M 13/00

(52) U.S. Cl. 248/206.2; 248/288.31

(57) ABSTRACT

A support device includes a base, a support tube, and a support bracket. The support tube includes a plurality of support units coaxially connected together in order, the support tube has a first end fixed to the base, and a second end opposite to the first end. The support bracket is adjustably mounted to the base via the support tube, the support bracket is fixed to the second end of the support tube. Each support unit of the support tube includes a linking base and a linking head opposite to the linking base, the linking base of each support unit is adjustably ball hinged with the linking head of one adjacent support unit.

### BACKGROUND

1. Technical Field

The present disclosure generally relates to support devices, and particularly to a support device applied for supporting an electronic device.

2. Description of Related Art

Many support devices include a base, a support rod, and a support bracket. The support rod is fixed on the base. The support bracket is fixed to a distal end of the support rod, away from the base, for clamping an electronic device having a display screen, such as a tablet computer, an electronic navigation device, for example.

However, the existing support device generally has a big volume taking up a large space in use. In addition, the height of the existing support device cannot be adjusted and is also hard to adjust a proper view angle of the electronic device.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views, and all the views are schematic.

FIG. 1 shows an assembled, isometric view of an embodiment of a support device.

FIG. 2 shows an exploded, isometric view of the support device of FIG. 1, wherein, the support device includes a base, a support tube and a support bracket.

FIG. 3 shows an isometric view of a support unit of the support tube of FIG. 2.

FIG. 4 is similar to FIG. 3, but viewed from another aspect.

FIG. 5 shows a partial cross-section view of the support tube of FIG. 2.

### DETAILED DESCRIPTION

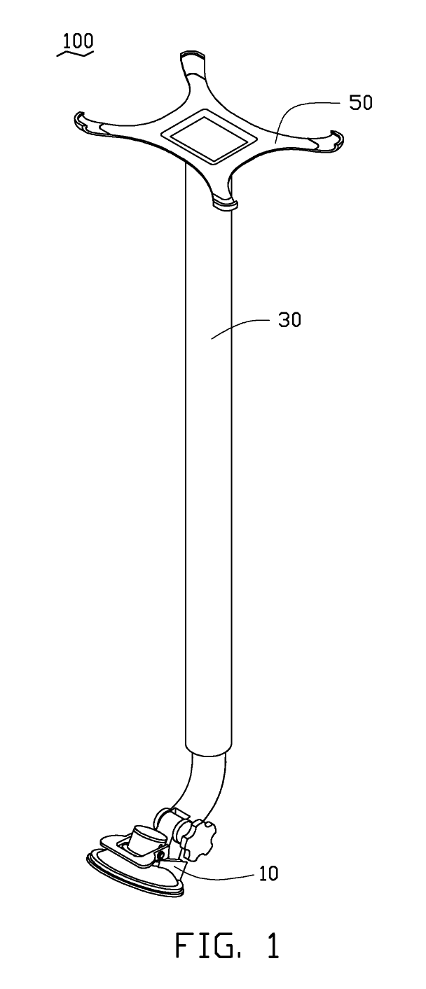

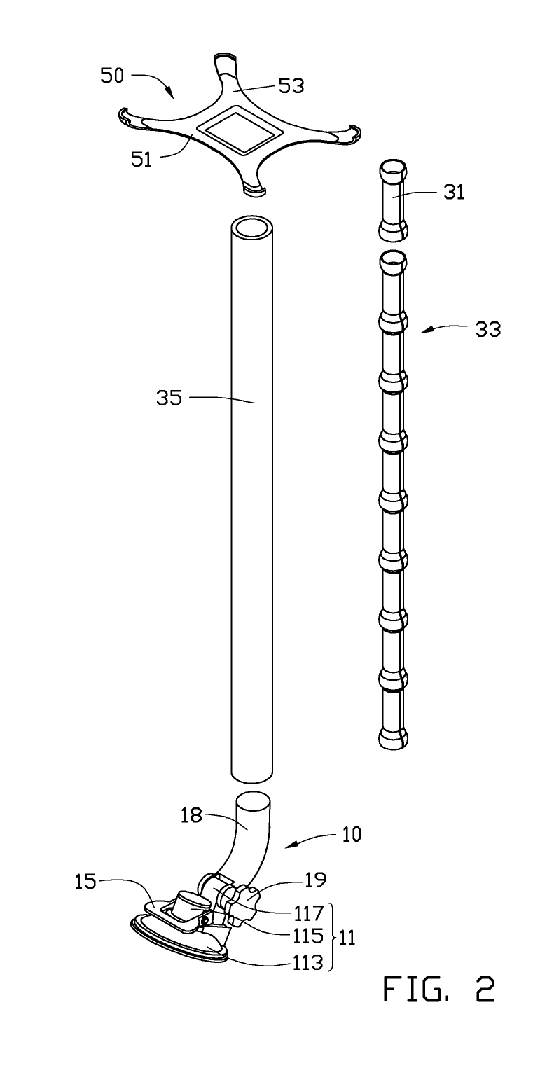

FIGS. 1 and 2, show an embodiment of a support device 100. The support device 100 is applied for supporting and clamping an electronic device (not shown) with a display screen, such as a panel computer, a portable navigating device, for example. The support device 100 includes a base 10, a support tube 30 and a support bracket 50. The support bracket 50 is adjustably mounted to the base 10 via the support tube 30 for clamping the electronic device.

The base 10 includes a suction cup 11, a pulling ring 15, a connecting member 18, and an adjusting member 19. The suction cup 11 is capable of firmly attaching to an object by sucking on a smooth surface. The suction cup 11 includes a substantially hollow semi-spherical suction body 113, an extruding portion 115, and a mounting portion 117. The extruding portion 115 is substantially cylindrical and formed on an outer surface of a substantially dome portion of the suction body 113. In use, the extruding portion 115 is pushed toward the suction body 113 to exhaust inner air in the suction body 113, thereby facilitating the suction body 113 to firmly attach with suction onto the smooth surface of the object. The mounting portion 117 is formed on the suction body 133 and positioned adjacent to the extruding portion 115. The pulling ring 15 is hinged to a distal end of the extruding portion 115 for facilitating the operation of the extruding portion 115. The connecting member 18 is a substantially arc-shaped body in the illustrated embodiment. A first end of the connecting member 18 is adjustably connected to the mounting portion 117 via the adjusting member 19. In the illustrated embodiment, the adjusting member 19 is an adjusting bolt for adjusting a relative angle of the connecting member 18 and the mounting portion 117.

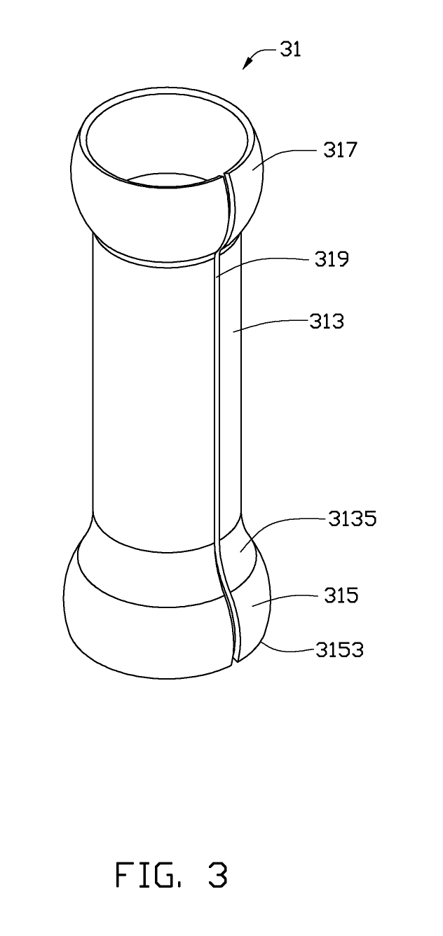

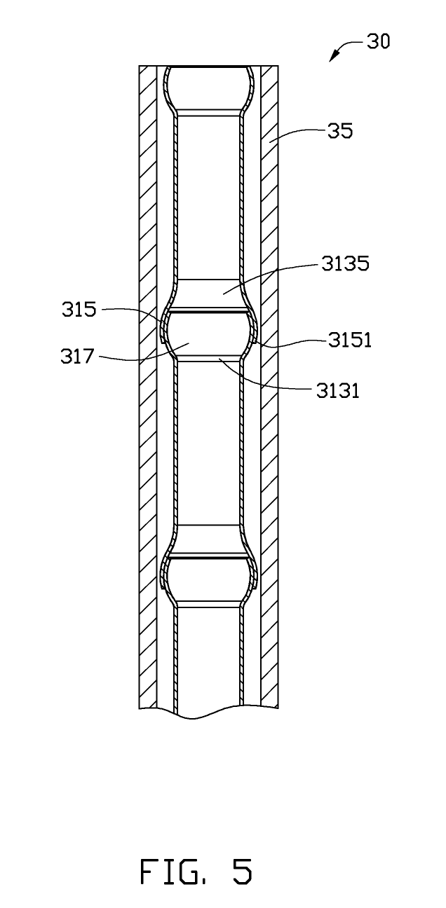

FIGS. 3 and 5, illustrate the support tube 30 made of flexible material and bendable to a certain range. A first end of the support tube 30 is fixed to the connecting member 18, and a second end of the support tube 30 opposite to the first end is fixed with the support bracket 50. The support tube 30 includes an inner tube 33 and a protective sleeve 35 sleeved on the inner tube 33. The inner tube 33 includes a plurality of hollow support units 31 adjustably connected together in order. Each support unit 31 includes a substantially hollow cylindrical linking body 313, a linking head 317 coaxially formed on a first end 3131 of the linking body 313, and a linking base 315 coaxially formed on the linking body 313, opposite to the first end 3131. The linking base 315 and the linking head 317 are both substantially hollow semi-spherical in the illustrated embodiment. In assembly, the linking base 315 of each support unit 31 is adjustably ball hinged with the linking head 317 of one adjacent support unit 31. In one embodiment, the linking body 313 may be a solid cylindrical body, one of the linking base 315 and the linking head 317 may be a solid semi-spherical body.

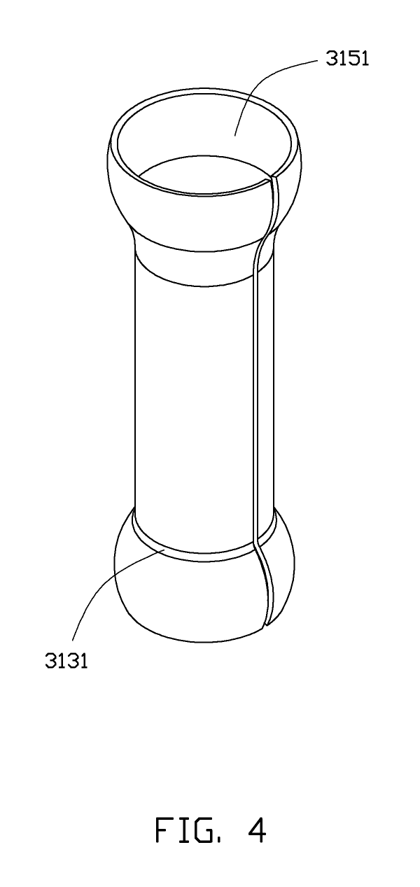

Also referring to FIG. 4, the linking base 315 defines a substantially hollow semi-spherical engaging portion 3151 corresponding to the linking head 317, and includes a positioning end 3153. The linking head 317 has a dimension substantially the same as the engaging portion 3151, for being capable of pivotally engaging with the linking base 315. In the illustrated embodiment, the linking base 315 and the linking head 317 are integrally formed with the linking body 313.

In the illustrated embodiment, the support unit 31 further defines a buffer slot 319 along an axial direction of the support unit 31.

The protective sleeve 35 is a substantially hollow tube made of soft material, such as rubber, and plastic, for example. The protective sleeve 35 is sleeved on and coaxially coils around the inner tube 33.

The support bracket 50 includes a substantially rectangular support plate 51 and four clamping arms 53 evenly extending and bending from a peripheral edge of the support plate 51. The four clamping arms 53 and the support plate 51 cooperatively define a receiving space (not labeled) for receiving the electronic device. It should be noted that the number of the clamping arms 53 is not limited to four, it can also be two, three or more than four, according to an actual need.

When assembling the support device 100, the plurality of support units 31 are coaxially connected together in order, to form the inner tube 33, among which, the linking base 315 of each support unit 31 is adjustably ball hinged with the linking head 317 of one adjacent support unit 31. The linking head 317 of one corresponding support unit 31 is rotatably engaged into and received within the corresponding engaging portion 3151 of one adjacent support unit 31. After that, the protective sleeve 35 is sleeved on and coaxially coiled around the inner tube 33, to finish the assembly of the support tube 30. A first end of the inner tube 33 is fixed to the connecting member 18 of the base 10. The support plate 51 is fixed to a second end of the inner tube 33 opposite to the first end of the inner tube 33, to finish the assembly of the support device 100.

In use, the suction body 113 of the base 10 is capable of being firmly attached on a plain surface of the object, by pulling the pulling ring 15 and resisting against the extruding portion 115 of the base 10. The pre-clamped electronic device is placed on and firmly clamped by the support bracket 50. A view angle and a height of the electronic device relative to the surface can be adjusted by bending and/or rotating the support tube 30. When the support tube 30 is bent, the positioning end 3153 of each support unit 31 is capable of resisting against one corresponding end portion of the linking body 313, positioned adjacent to the positioning end 3153, thereby maintaining the whole support tube 30 at a proper bent angle. An inclined angle of the support tube 30 relative to the base 10 can also be adjusted by the adjusting member 19. In addition, since the plurality of the support units 31 are adjustably ball hinged together in order, a rotating angle of the support bracket 50 together with the electronic device relative to the base 10 is adjusted by rotating the support bracket 50.

In an alternative embodiment, the protective sleeve 35 is omitted, namely, the support tube 30 merely consists of a plurality of support units 31 ball hinged together in order.

Finally, while various embodiments have been described and illustrated, the disclosure is not to be construed as being limited thereto. Various modifications can be made to the embodiments by those skilled in the art without departing from the true spirit and scope of the disclosure as defined by the appended claims.

What is claimed is:

1. A support device comprising:
a base;
a support tube comprising a plurality of support units coaxially connected together in order, the support tube having a first end fixed to the base, and a second end opposite to the first end; and
a support bracket adjustably mounted to the base via the support tube, the support bracket being fixed to the second end of the support tube;
wherein, each support unit of the support tube comprises a linking base and a linking head opposite to the linking base, the linking base of each support unit is adjustably ball hinged with the linking head of one adjacent support unit.

2. The support device of claim 1, wherein the linking base and the linking head are both substantially semi-spherical, the linking base defines a substantially hollow semi-spherical engaging portion rotatably engaging with a corresponding linking head.

3. The support device of claim 1, wherein each support unit further defines a buffer slot along an axial direction of the support unit.

4. The support device of claim 1, wherein the support unit further comprises a substantially hollow cylindrical linking body, the linking head and the linking base are formed at opposite ends of the linking body.

5. The support device of claim 4, wherein the linking base of each support unit comprises a positioning end, the positioning end is capable of resisting against one corresponding end portion of the linking body of one adjacent support unit, thereby maintaining two adjacent support units at a proper bended angle.

6. The support device of claim 1, wherein the support tube further comprises a protective sleeve sleeved on and coaxially coiled around the plurality of support units.

7. The support device of claim 1, wherein the base comprises a suction cup and a connecting member connected to the suction cup, a distal end of the connecting member away from the suction cup is fixed with the first end of the support tube.

8. The support device of claim 7, wherein the suction cup comprises a suction body, and a mounting portion formed on the suction body; the base further comprises an adjusting member, the connecting member is adjustably connected to the mounting portion of suction cup via the adjusting member.

9. The support device of claim 8, wherein, the suction cup further comprises an extruding portion formed adjacent to the mounting portion, the base further comprises a pulling ring hinged to the extruding portion.

10. The support device of claim 1, wherein the support bracket comprises a support plate and a plurality of clamping arms extending and bending from a peripheral edge of the support plate, the clamping arms and the support plate cooperatively define a receiving space for receiving an electronic device.

11. A support device for an electronic device, the support device comprising:
a base;
a support tube rotatably hinged to the base; and
a support bracket fixed to a distal end of the support tube, away from the base, for supporting and clamping the electronic device;
wherein, the support tube comprises a plurality of support units coaxially connected together in order, each support unit comprises a linking base and a linking head opposite to the linking base, the linking base of each support unit is adjustably ball hinged with the linking head of one adjacent support unit.

12. The support device of claim 11, wherein the linking base and the linking head are both substantially semi-spherical, the linking base defines a substantially hollow semi-spherical engaging portion rotatably engaging with a corresponding linking head.

13. The support device of claim 12, wherein each support unit further comprises a substantially hollow cylindrical linking body, the linking head and the linking base are oppositely formed at two ends of the linking body; the support unit further defines a buffer slot along an axial direction of the support unit.

14. The support device of claim 13, wherein the support tube further comprises a protective sleeve sleeved on and coaxially coiled around the plurality of support units; the support bracket comprises a support plate and a plurality of clamping arms extending and bending from a peripheral edge of the support plate, the clamping arms and the support plate cooperatively define a receiving space for receiving the electronic device.

15. The support device of claim 13, wherein, the base comprises a suction cup and a connecting member connected to the suction cup, a distal end of the connecting member away from the suction cup is fixed with the first end of the support tube.

16. The support device of claim 15, wherein the suction cup comprises a suction body, and a mounting portion formed on the suction body; the base further comprises an adjusting member, the connecting member is adjustably hinged to the mounting portion of suction cup via the adjusting member.

17. The support device of claim 16, wherein, the suction cup further comprises an extruding portion formed adjacent to the mounting portion, the base further comprises a pulling ring hinged to the extruding portion.
